(19) United States
(12) Patent Application Publication
(10) Pub. No.: US 2011/0037658 A1
(43) Pub. Date: Feb. 17, 2011

(54) MULTI-LAYER THIN FILM INTERNAL ANTENNA, TERMINAL HAVING THE SAME, AND METHOD FOR MANUFACTURING MULTI-LAYER THIN FILM INTERNAL ANTENNA

(75) Inventor: Book-Sung PARK, Seoul (KR)

Correspondence Address: H.C. PARK & ASSOCIATES, PLC, 8500 LEESBURG PIKE, SUITE 7500, VIENNA, VA, 22182, US

(73) Assignee: PANTECH CO., LTD., Seoul (KR)

(21) Appl. No.: 12/776,183

(22) Filed: May 7, 2010

(30) Foreign Application Priority Data
Aug. 17, 2009 (KR) 10-2009-0075749

(51) Int. Cl. H01Q 1/38; C23C 14/14

(52) U.S. Cl. 343/700 MS; 204/192.15

(57) ABSTRACT

A multi-layer thin film internal antenna is formed by sequentially sputter depositing a deposition layer and a conductive layer on a substrate. The deposition layer and the conductive layer may be formed using, as target materials, nickel and silver, respectively. A protecting layer may be further sputter deposited on the conductive layer.

### CROSS-REFERENCE TO RELATED APPLICATION

This application claims priority from and the benefit of Korean Patent Application No. 10-2009-0075749, filed on Aug. 17, 2009, which is hereby incorporated by reference for all purposes as if fully set forth herein.

### BACKGROUND

1. Field

The present disclosure relates to an internal antenna, a terminal including the internal antenna, and a method for manufacturing an internal antenna.

1. Discussion of the Background

Due to developments of mobile communications and multimedia, a mobile terminal that supports complex functionality is increasing. Mobile terminals generally adopt an internal antenna design, instead of an external antenna, for communication to thereby provide portability and convenience.

For example, a monopole antenna, a planar inverted F antenna (PIFA), and a dielectric antenna may be used for the internal antenna. The monopole antenna and the PIFA, which are relatively inexpensive, are widely used. The monopole antenna, the PIFA, and the dielectric antenna may be formed by fixing a metal to a carrier base. Accordingly, to install a monopole or PIFA internal antenna in a portable terminal, the carrier base may be separately provided, which may occupy more space inside the mobile terminal and limit a size reduction of the mobile terminal.

### SUMMARY OF THE INVENTION

Exemplary embodiments of the present invention provide an internal antenna that may have a multi-layer thin film structure formed using a sputtering deposition method.

Exemplary embodiments of the present invention also provide a terminal including the multi-layer thin film internal antenna.

Exemplary embodiments of the present invention also provide a method for manufacturing the multi-layer thin film internal antenna.

Additional features of the invention will be set forth in the description which follows, and in part will be apparent from the description, or may be learned by practice of the invention.

An exemplary embodiment provides a multi-layer thin film internal antenna including a sputter deposited deposition layer disposed on a substrate and comprising a first conductive material; and a sputter deposited conductive layer disposed on the deposition layer and comprising a second conductive material.

An exemplary embodiment provides a multi-layer thin film internal antenna including a plurality of sputter deposited layers being each comprising conductive materials, the layers being disposed in a multi-layer structure on a substrate, wherein total thickness of the layers may be 1.0 μm to 1.6 μm.

An exemplary embodiment provides a method for manufacturing a multi-layer thin film internal antenna, the method including: sputter depositing, in a pattern, a deposition layer on a substrate of a terminal body using a first conductive material; and sputter depositing, in a pattern, a conductive layer on the substrate using a second conductive material.

An exemplary embodiment provides a terminal including: a terminal body including a substrate; and a multi-layer thin film internal antenna disposed in a multi-layer structure on the substrate, wherein the antenna comprises a sputter deposited deposition layer including a first conductive material on the substrate, and a sputter deposited conductive layer including a second conductive material on the deposition layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further is understanding of the invention and are incorporated in and constitute a part of this specification, illustrate exemplary embodiments of the invention, and together with the description serve to explain the principles of the invention.

FIG. 1 is a perspective view illustrating a terminal including a multi-layer thin film internal antenna according to an embodiment of the present invention.

FIG. 2 is a cross-sectional view illustrating a multi-layer thin film internal antenna according to an embodiment of the present invention.

FIG. 3 is a graph illustrating a correlation between a frequency and a thickness of a sputtering material.

FIG. 4 is a graph illustrating a correlation between a frequency and a thickness of the multi-layer thin film internal antenna of FIG. 2.

FIG. 5 is an image obtained by an actual photograph of the multi-layer thin film internal antenna of FIG. 2 using a Scanning Electron Microscope (SEM).

FIG. 6 is a flowchart illustrating a method for manufacturing the multi-layer thin film internal antenna of FIG. 2 according to an embodiment of the present invention.

FIG. 7 is a perspective view illustrating a state where a substrate is provided according to an embodiment of the present invention.

FIG. 8 is a perspective view illustrating a state where a mask is provided on the substrate of FIG. 7.

FIG. 9 is a perspective view illustrating an operation of manufacturing the multi-layer thin film internal antenna on the substrate of FIG. 8 using a sputtering deposition method.

FIG. 10 is a perspective view illustrating a state of the multi-layer thin film internal antenna provided on the substrate of FIG. 8.

FIG. 11 is a cross-sectional view illustrating a multi-layer thin film internal antenna according to an exemplary embodiment of the present invention.

FIG. 12 is a graph illustrating a correlation between a frequency and a thickness of the multi-layer thin film internal antenna of FIG. 11.

FIG. 13 is a flowchart illustrating a method for manufacturing the multi-layer thin film internal antenna of FIG. 11.

FIG. 14 and FIG. 15 are images obtained by measuring a conductive layer formed of silver and deposited on a deposition layer formed of nickel, using an Atomic Force Microscope (AFM) to verify a surface flatness of a multi-layer thin film internal antenna according to an embodiment of the present invention.

FIG. 16A and FIG. 16B are analysis diagrams illustrating X-ray diffraction pattern images obtained by using an X-ray Diffractometer (XRD) capable of measuring a material component composition ratio of a deposition layer and a conductive layer of a multi-layer thin film internal antenna according to an embodiment of the present invention.

FIG. 17 and FIG. 18 are graphs illustrating results of measuring a standing wave ratio (SWR) and S₁₁ of a multi-layer thin film internal antenna according to an embodiment of the present invention.

FIG. 19 is a graph illustrating results of measuring an actual SWR of a multi-layer thin film internal antenna according to an embodiment of the present invention.

FIG. 20A, FIG. 20B, FIG. 20C, and FIG. 20D are images the multi-layer thin film internal antenna of FIG. 11 for each operation using a SEM, according to an exemplary embodiment of the present invention.

FIG. 21A, FIG. 21B, and FIG. 21C are analysis diagrams illustrating X-ray is diffraction pattern images obtained by using an XRD capable of measuring a material component composition ratio of a deposition layer, a conductive layer, and a protecting layer of a multi-layer thin film internal antenna according to an exemplary embodiment of the present invention.

FIG. 22 and FIG. 23 are graphs illustrating results of measuring an SWR and S₁₁ of a multi-layer thin film internal antenna according to an exemplary embodiment of the present invention.

FIG. 24 and FIG. 25 are graphs illustrating results of measuring an actual SWR of a multi-layer thin film internal antenna using a network analyzer according to an exemplary embodiment of the present invention.

FIG. 26A, FIG. 26B, and FIG. 26C are radiation patterns with respect to an E-plane and an H-plane that are two-dimensional (2D) antenna gain measurement results of a multi-layer thin film internal antenna according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element is referred to as being “connected to” another element, it can be directly connected to the other element or intervening elements may be present.

Hereinafter, a multi-layer thin film internal antenna, a terminal including the internal antenna, and a method for manufacturing the internal antenna according to exemplary embodiments of the present invention will be described.

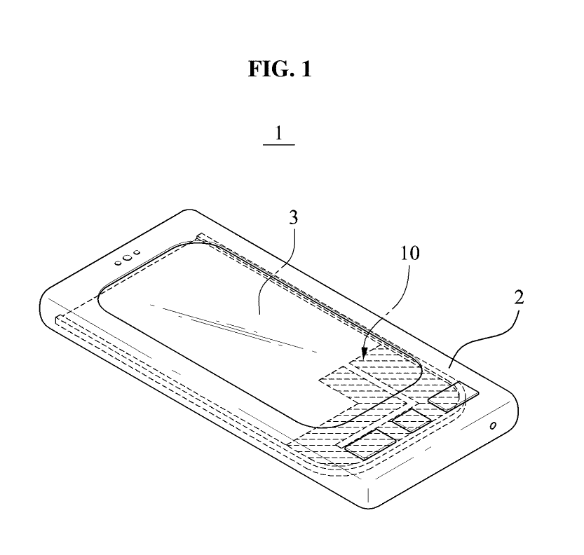

Referring to FIG. 1, a terminal 1 includes a terminal body 2 and an antenna 10 provided within the terminal body 2. Here, the terminal 1 may be a mobile communication terminal, for example, a mobile phone. However, aspects of the present invention are not limited thereto.

The terminal body 2 corresponds to a body of the terminal 1, and may be embedded with or may include a substrate 3. The substrate 3 may be formed of, for example, a polycarbonate.

Although the terminal body 2 is not illustrated in detail, a speaker, a microphone, a plurality of keys, a display panel, and the like may be provided to the terminal body 2.

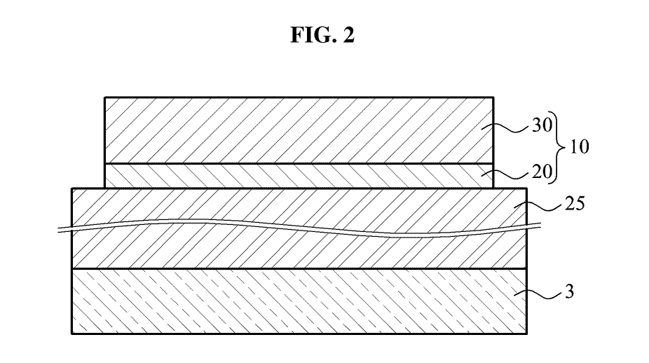

The antenna 10 may be embedded in or disposed on the terminal body 2. Specifically, the antenna 10 may have a multi-layer thin film structure and may be disposed in a pattern according to a sputtering deposition method. As shown in FIG. 2, the antenna 10 may have a heterostructure that includes a deposition layer 20 and a conductive layer 30. Hereinafter, the antenna 10 will be referred to as a heterostructure internal antenna 10.

The deposition layer 20 may be formed of a conductive material and may be disposed on the substrate 3 by using a sputtering deposition method. The deposition layer 20 may include a sputtering target material, for example, nickel. The deposition layer 20 may be formed to have a thickness of 2500 Å to 3500 Å by sputter depositing the nickel at a power of 6.5 kW to 7.5 kW in a plasma atmosphere for 175 seconds to 185 seconds. For example, the deposition layer 20 may be disposed at a thickness of 3000 Å by sputter depositing the nickel at the power of 7 kW in the plasma atmosphere for 180 seconds.

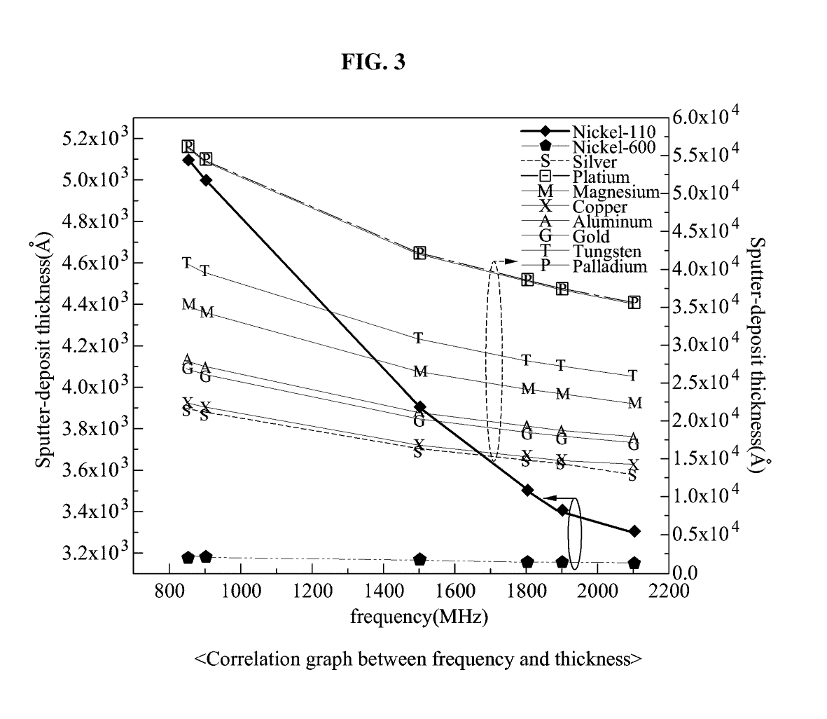

FIG. 3 is a graph illustrating a frequency and a thickness of a sputtering material. The graph illustrates a thickness estimation with respect to exemplary metals that may be deposited using the sputtering deposition method. A deposition thickness per frequency of deposition may be determined for each of the ten metals. Referring to the graph of FIG. 3, a depth from which signals may flow from a layer for each frequency may be determined based on a permeability characteristic of each of the metals.

Due to a material characteristic of the substrate 3, the substrate 3 disposed in the terminal 2 may have a rough surface shape. Accordingly, as shown in FIG. 2, a planarization layer 25 may be disposed between the substrate 3 and the deposition layer 20 to planarize the substrate 3. The planarization layer 25 may be disposed on the substrate 3 to a thickness of 75 μm to 85 μm by spraying a hardener, such as WP100, on the substrate 3 at a temperature of 75° C. to 85° C. for 85 minutes to 95 minutes. For example, the planarization layer 25 may be deposited on the substrate 3 to a thickness of 80 μm by spraying the hardener at a temperature of 80° C. for 90 minutes.

Similar to the deposition layer 20, the conductive layer 30 may be formed of a same or different conductive material and may be disposed on the deposition layer 20 using the sputtering deposition method. The conductive layer 30 may be silver that has an excellent conductivity. The conductive layer 30 may be disposed at a thickness of 7500 Å to 8500 Å by sputter depositing the silver at a power of 6.5 kW to 7.5 kW in a plasma atmosphere for 1450 seconds to 1550 seconds. For example, the conductive layer 30 may be deposited to a thickness of 8000 Å by sputter depositing the silver at the power of 7 kW in the plasma atmosphere for 1500 seconds.

The deposition layer 20 and the conductive layer 30 formed using the sputtering deposition method may be deposited at a distance of about 70 mm from the substrate 3 at an air flow of 70 sccm. Example sputtering deposition criteria for the deposition layer 20 and the conductive layer 30 are shown in the following Table 1:

TABLE 1

| | | | Distance target- | |
|---|---|---|---|---|
| Target material | Power | Air flow | substrate | Time |
| Deposition layer (Ni) | 7 kW | 70 sccm | 70 mm | 180 s |
| Conductive layer (Ag) | 7 kW | 70 sccm | 70 mm | 1500 s |

The heterostructure internal antenna 10 of FIG. 2 may be disposed in a multi-layer thin film structure to have a thickness of 11000 Å by using the nickel and the silver. Electrons may flow within a conductor at a low frequency and may flow along the surface of the conductor while a frequency changes from the low frequency to a high frequency. Accordingly, even when a thickness of the conductive layer 30 is thin, the heterostructure internal antenna 10 may compensate for the thin thickness with the deposition layer 20.

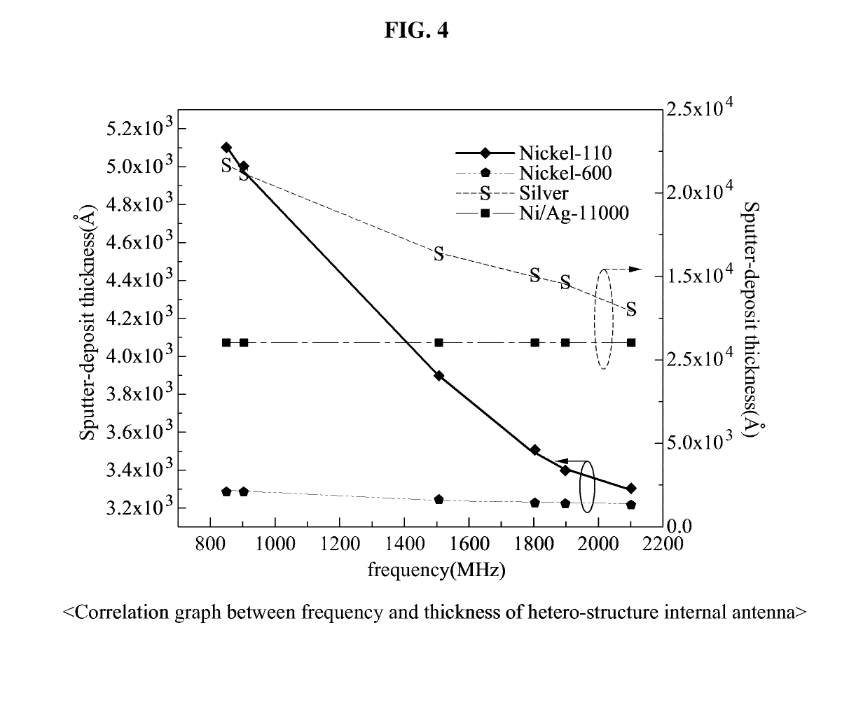

Characteristics of the heterostructure internal antenna 10 are shown in a graph of FIG. 4. Compared to an example of individually utilizing either nickel or silver, it can be seen from the graph of FIG. 4 that the heterostructure internal antenna 10 including the deposition layer 20 and the conductive layer 30 formed of the nickel and the silver, respectively, shows an excellent thickness characteristic for each frequency.

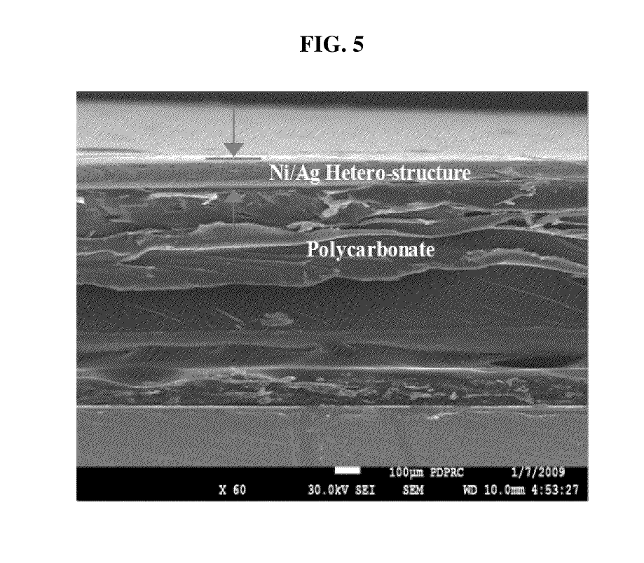

FIG. 5 is a Scanning Electron Microscope (SEM) image of a heterostructure internal antenna 10. The image shows an interface of the heterostructure internal antenna 10. The SEM image of the heterostructure internal antenna 10 was measured at a 30,000× magnitude, a gun voltage of 30.0 kV, a working distance of 8.8 mm, and a total thickness of 100 μm including a thickness of the substrate 3.

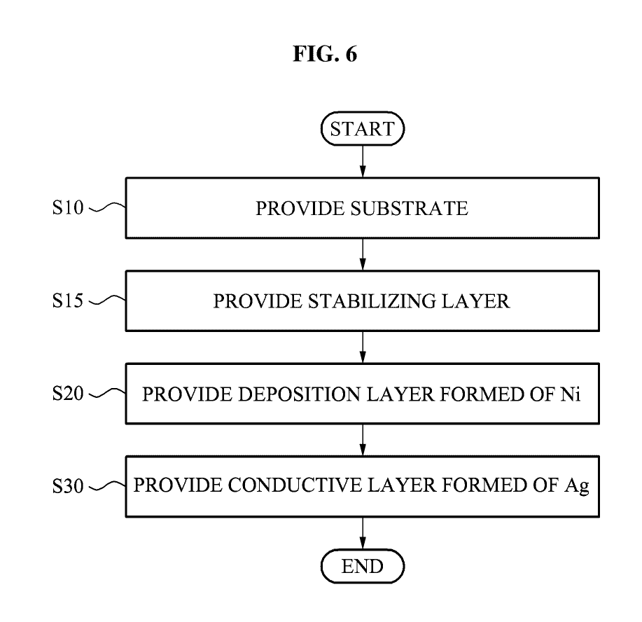

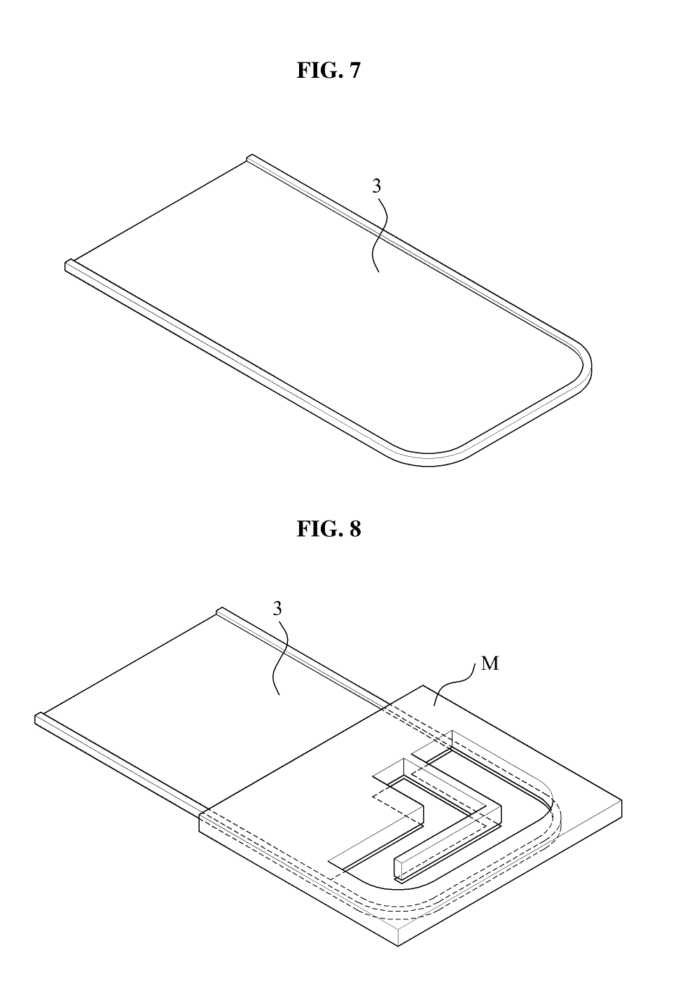

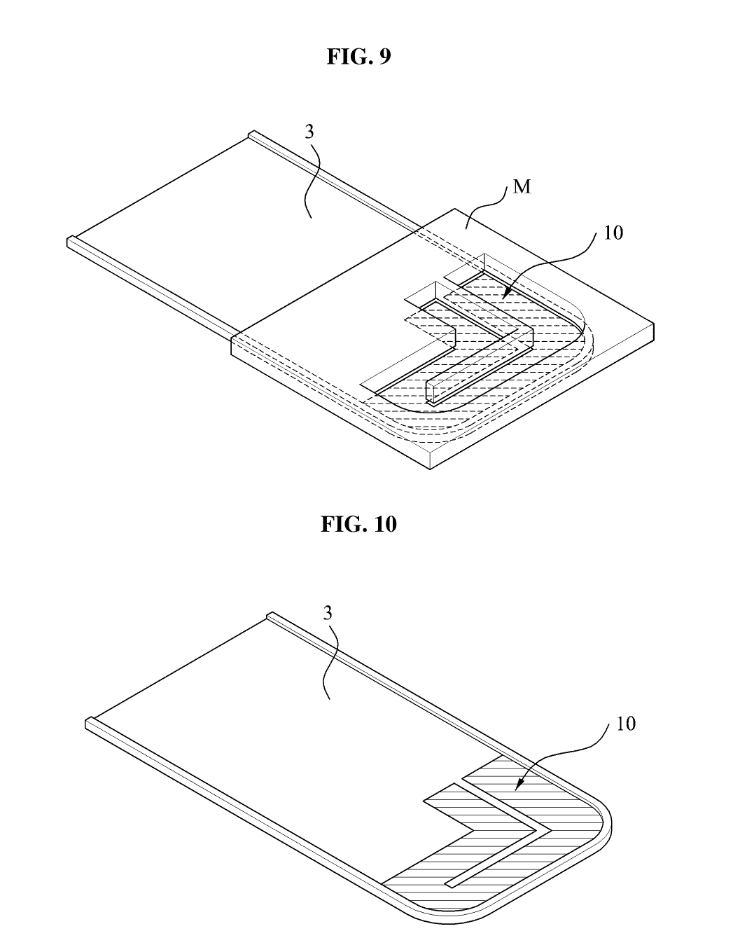

Hereinafter, a method for manufacturing a heterostructure internal antenna 10 will be described with reference to FIG. 6, FIG. 7, FIG. 8, FIG. 9, and FIG. 10.

Referring to FIG. 6, in operation S10, the substrate 3 to be mounted with the heterostructure internal antenna 10 may be provided. The substrate 3 may be formed of a polycarbonate. The substrate 3 mounted with the heterostructure internal antenna 10 may be disposed on or within the terminal body 2.

In operation S15, the planarization layer 25 may be provided by spraying a hardener on the substrate 3. For example, the planarization layer 25 may be provided on the substrate 3 to have a thickness of 80 μm by spraying the hardener at a temperature of 80° C. for 90 minutes, to thereby stabilize or planarize the non-uniform surface of the substrate 3. FIG. 7 is a perspective view illustrating a state where the substrate 3 is provided.

When the planarization layer 25 is provided on the substrate 3 in operation S15, the deposition layer 20 and the conductive layer 30 may be sequentially provided using a sputtering deposition method in operations S20 and S30. As described above, the deposition layer 20 and the conductive layer 30 may be formed using, as a sputtering target material, nickel and silver, respectively. The deposition layer 20 may be formed to have a thickness of 3000 Å by sputter depositing the nickel at the power of 7 kW in a plasma atmosphere for 180 seconds. Also, the conductive layer 30 may be formed to have a thickness of 8000 Å by sputter depositing the silver at a power of 7 kW in a plasma atmosphere for 1500 seconds.

As shown in FIG. 8 and FIG. 9, the deposition layer 20 and the conductive layer 30 sequentially provided using the sputtering deposition method may be deposited in a pattern using a mask M. For example, as shown in FIG. 8, the mask M having an antenna pattern may be disposed on the substrate 3. Here, a planar inverted F antenna (PIFA)-typed antenna pattern is illustrated.

As shown in FIG. 9, the sputtering deposition process using the nickel (Operation S20) and the silver (Operation S30) may be sequentially performed with the mask M arranged on the substrate 3. As shown in FIG. 10, when the sputtering deposition process is completed, the mask M may be removed. Accordingly, the heterostructure internal antenna 10 is completed. Further, the mask M may be applied before or after any of the above-described operations such that one or more of the planarization layer 25, the deposition layer 20, and/or the conductive layer 30 may be formed in the shape as determined by the mask M.

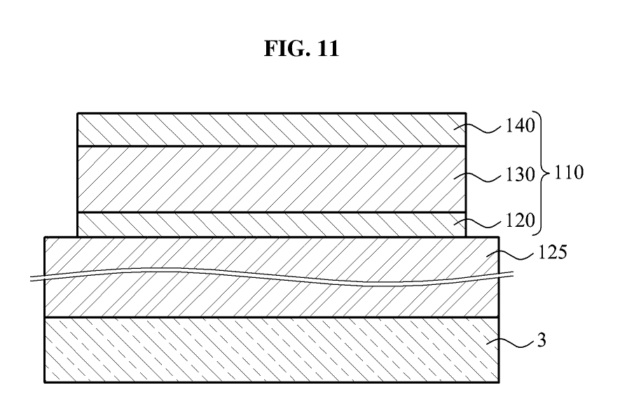

FIG. 11 is a cross-sectional view illustrating a multi-layer thin film internal antenna 110 according to an exemplary embodiment of the present invention. As shown in FIG. 11, the multi-layer thin film internal antenna 110 may be provided in a tri-structure that includes a deposition layer 120, a conductive layer 130, and a protecting layer 140 that are sequentially deposited on a substrate 3 using a sputtering deposition method. Before depositing the deposition layer 120 on the substrate 3 using the sputtering deposition method, a planarization layer 125 that planarizes the surface of the substrate 3 may be disposed on the substrate 3 by spraying a hardener on the substrate 3. Hereinafter, for ease of description, the multi-layer thin film internal antenna 110 will be referred to as a tri-structure internal antenna 110.

The deposition layer 120, the conductive layer 130, and the planarization layer 125 of FIG. 11 may be formed using the same methods as described above with respect to the deposition layer 20, the conductive layer 30, and the planarization layer 25 of FIG. 2. Further, the protecting layer 140 may be provided. Accordingly, further detailed descriptions related to the deposition layer 120, the conductive layer 130, and the planarization layer 125 will be omitted here.

The protecting layer 140 may be provided on the conductive layer 130 using the sputtering deposition method. Similar to the deposition layer 120, the protecting layer 140 may use the nickel as a sputtering target material and may be formed to have a thickness of 3500 Å to 4500 Å by sputter depositing the nickel at a power of 6.5 kW to 7.5 kW in a plasma atmosphere for 200 seconds to 300 seconds. For example, the protecting layer 140 may be formed to have a thickness of 4000 Å by sputter depositing the nickel at a power of 7 kW in a plasma atmosphere for 240 seconds. Through the above configuration, the tri-structure internal antenna 110 further including the protecting layer 140 may have a total thickness of 15000 Å. The protecting layer 140 may be deposited at a distance of about 700 mm from the substrate 3 at an air flow of 70 sccm. Example sputtering deposition criteria for the deposition layer 120, the conductive layer 130, and the protecting layer 140 are shown in the following Table 2:

TABLE 2

| | | | Distance target- | |
|---|---|---|---|---|
| Target material | Power | Air flow | substrate | Time |
| Deposition layer (Ni) | 7 kW | 70 sccm | 70 mm | 180 s |
| Conductive layer (Ag) | 7 kW | 70 sccm | 70 mm | 1500 s |
| Protecting layer (Ni) | 7 kW | 70 sccm | 70 mm | 240 s |

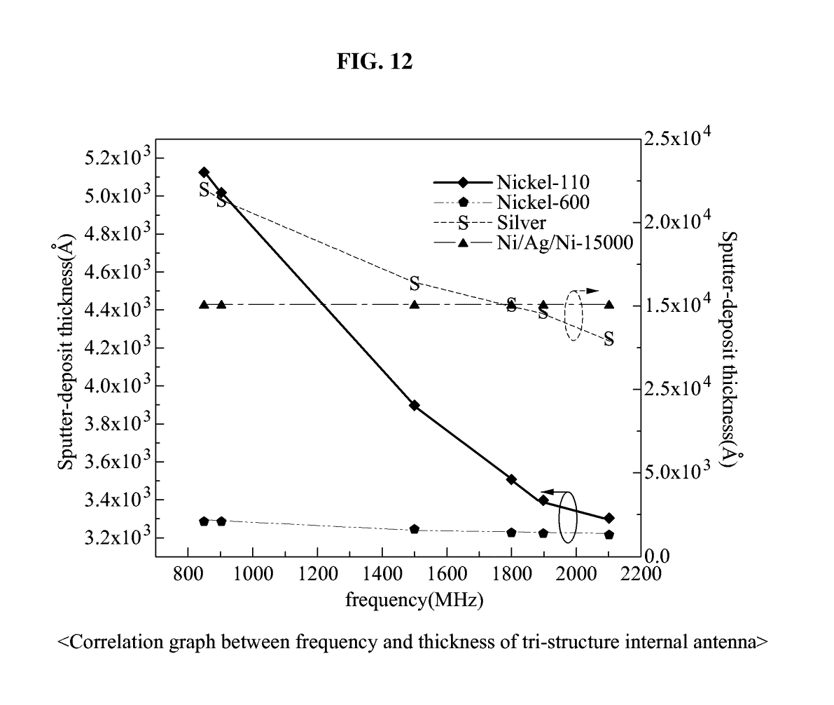

Characteristics of the tri-structure internal antenna 110 constructed as above are shown in a graph of FIG. 12. Compared to an example of individually utilizing either nickel or silver, it can be seen from the graph of FIG. 12 that the tri-structure internal antenna 110 including the deposition layer 120, the conductive layer 130, and the protecting layer 140 formed of the nickel, the silver, and the nickel, respectively, shows an excellent thickness characteristic for each frequency.

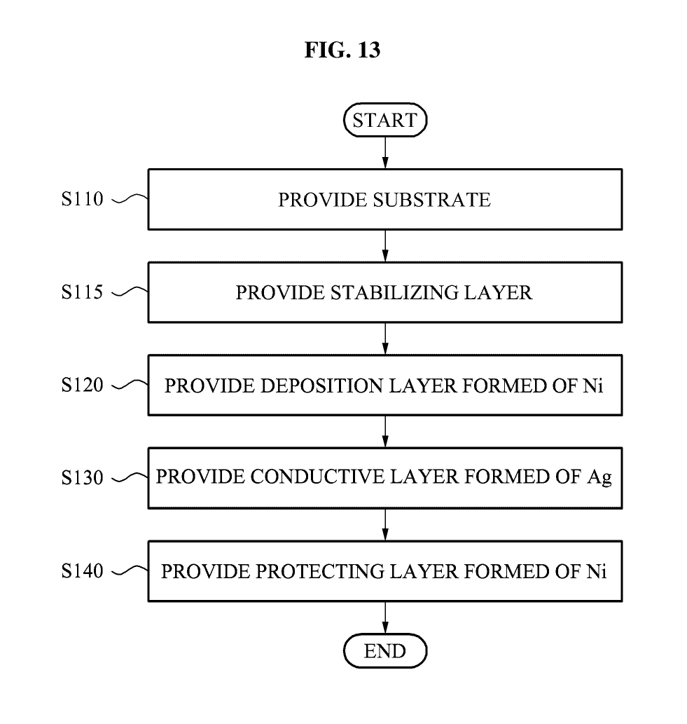

FIG. 13 is a flowchart illustrating a method for manufacturing the tri-structure internal antenna 110. Similar to the flowchart of FIG. 6 illustrating the method for manufacturing the heterostructure internal antenna 10, the substrate 3 may be provided in operation S110. In operation S115, the planarization layer 125 may be provided. In operations S120 and S130, the deposition layer 120 and the conductive layer 130 may be sequentially provided using nickel and silver as target materials, respectively, according to the criteria of the above Table 2. In operation S140, the protecting layer 140 may be provided on the conductive layer 130 by using the nickel as the target material and using the sputtering deposition method. The tri-structure internal antenna 110 is completed. As described above, a mask M may be applied before or after any of the above-described operations such that one or more of the planarization layer 25, the deposition layer 120, the conductive layer 130, and/or the protecting layer 140 may be formed in the shape as determined by the mask M

Hereinafter, a thin film surface of the heterostructure internal antenna 10 and the tri-structure internal antenna 10 will be described.

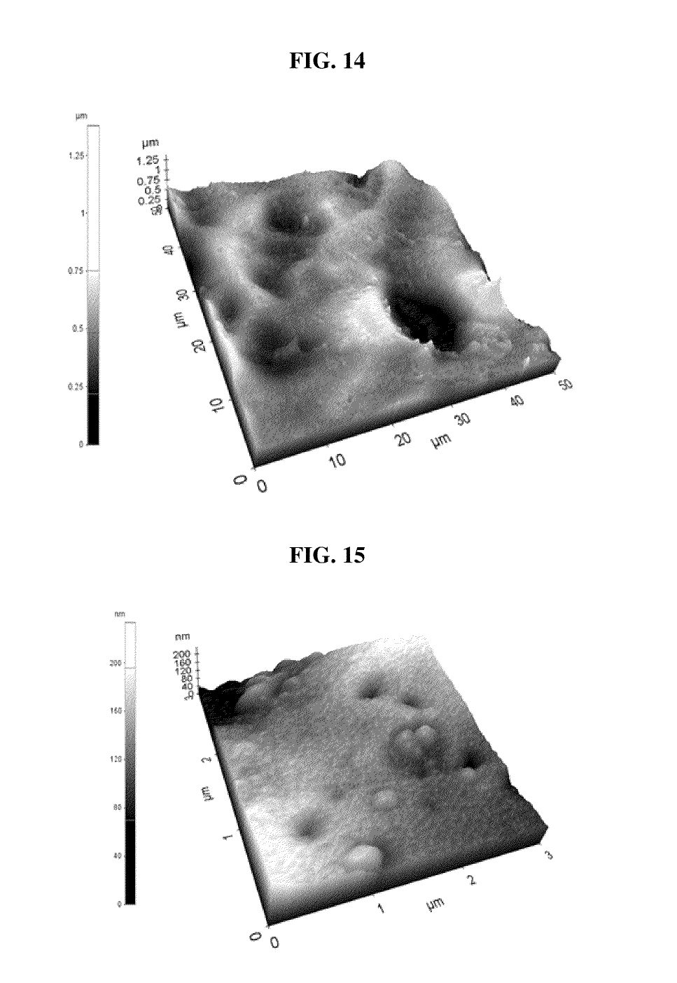

FIG. 14 and FIG. 15 are Atomic Force Microscope (AFM) images measuring the conductive layer 30 formed of the silver and deposited on the deposition layer 20 showing a surface flatness of the heterostructure internal antenna 10. FIG. 14 and FIG. 15 are of a 50 μm×50 μm red square and a 3 μm×3 μm red square, respectively, of the conductive layer 30. FIG. 14 and FIG. 15 show that a density of deposited molecules is stable and a surface destroying phenomenon may not occur as a translation result of the thin film surface of the heterostructure internal antenna 10.

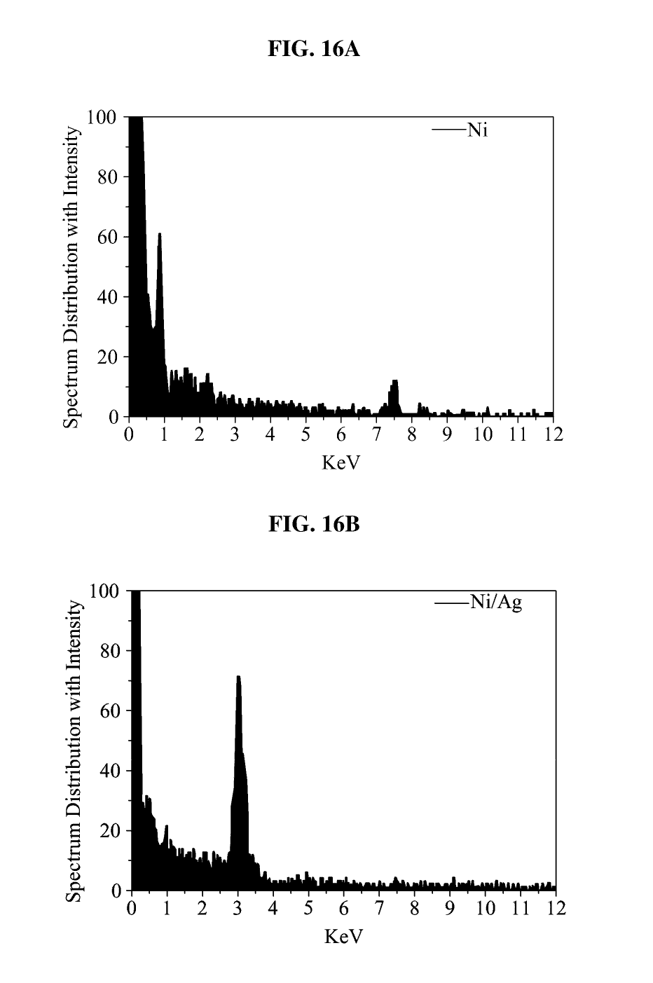

FIG. 16A and FIG. 16B are analysis diagrams illustrating X-ray diffraction pattern images obtained by using an X-ray Diffractometer (XRD) capable of representing a material component composition ratio of the deposition layer 20 of the heterostructure internal antenna 10 and the conductive layer 30 deposited on the deposition layer 20. FIG. 16A illustrates an analysis diagram based on a spectra image of the deposition layer 20, and FIG. 16B illustrates an analysis diagram based on a spectra image of the conductive layer 30 deposited on the deposition layer 20. A voltage applied to measure the material component composition ratio was 0 keV to 12 keV.

Referring to FIG. 16A, the deposition layer 20 shows the material component composition ratio at 0.743 keV, 0.762 keV, 0.851 keV, and 7.478 keV, and shows a peak-to-peak characteristic distribution composition ratio at 8.265 keV. Also, referring to FIG. 16B, the conductive layer 30 shows the material component composition ratio at 2.643 keV, 2.806 keV, and 2.984 keV, and shows the peak-to-peak characteristic distribution composition ratio at 3.151 keV.

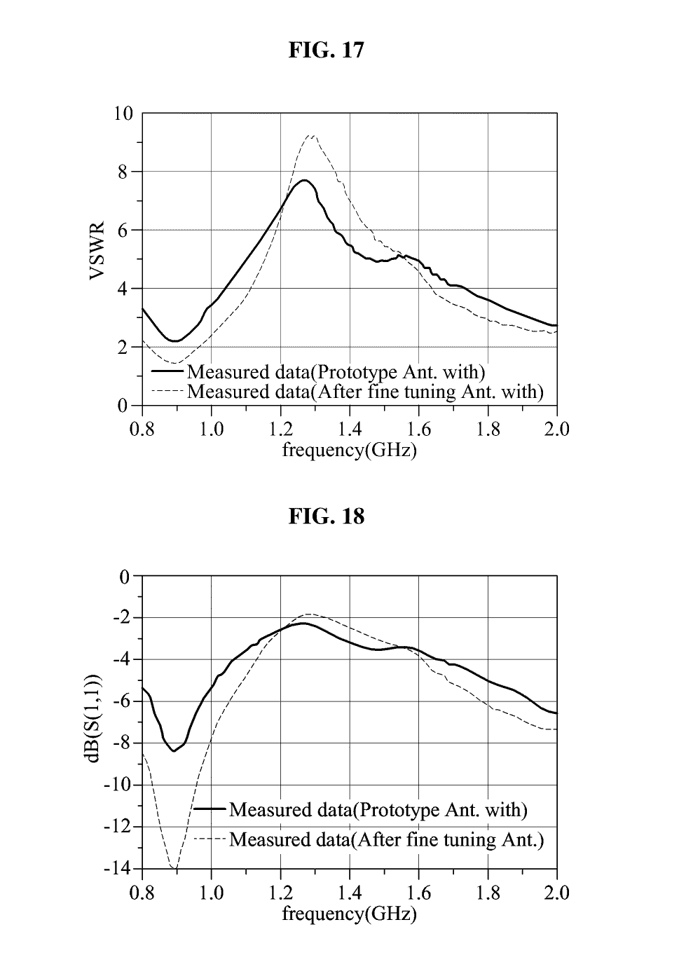

FIG. 17 and FIG. 18 are graphs illustrating results of measuring a standard wave ratio (SWR) and an S₁₁ s-parameter, respectively, of the heterostructure internal antenna 10. The graphs of FIG. 17 and FIG. 18 each show initial measurement values and optimized values. Here, a translation of the SWR of the heterostructure internal antenna 10 was performed by evaluating an SWR characteristic using a network analyzer. An operation of optimizing an s-parameter extracted from each antenna component using a matching network was performed. It can be seen from the graphs of FIG. 17 and FIG. 18 that the measured SWR and S₁₁ of the heterostructure internal antenna 10 exhibit stable characteristics.

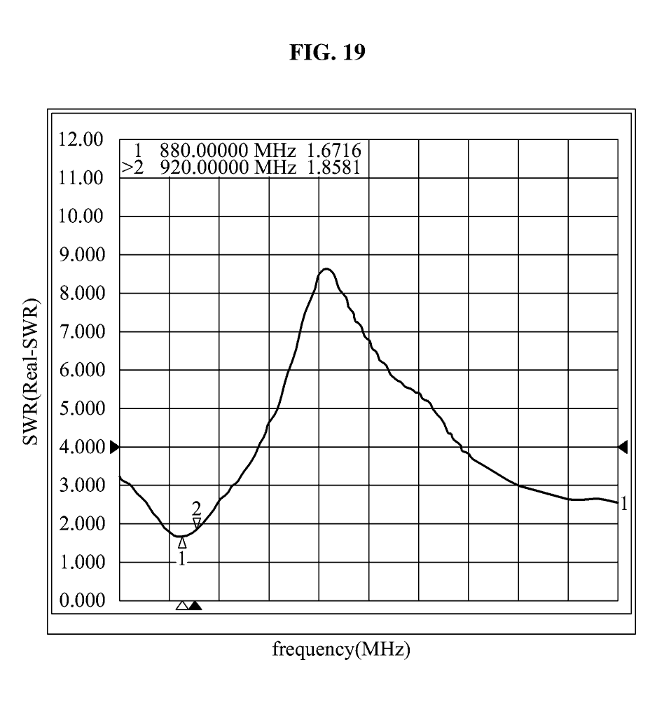

FIG. 19 is a graph illustrating results of measuring an actual SWR of the heterostructure internal antenna 10. FIG. 19 shows that the measured SWR characteristic of the heterostructure internal antenna 10 exhibits passive characteristic results of 1.715 and 1.882 at 820 MHz and 960 MHz, respectively, which indicate that the heterostructure internal antenna 10 may properly operate as an antenna.

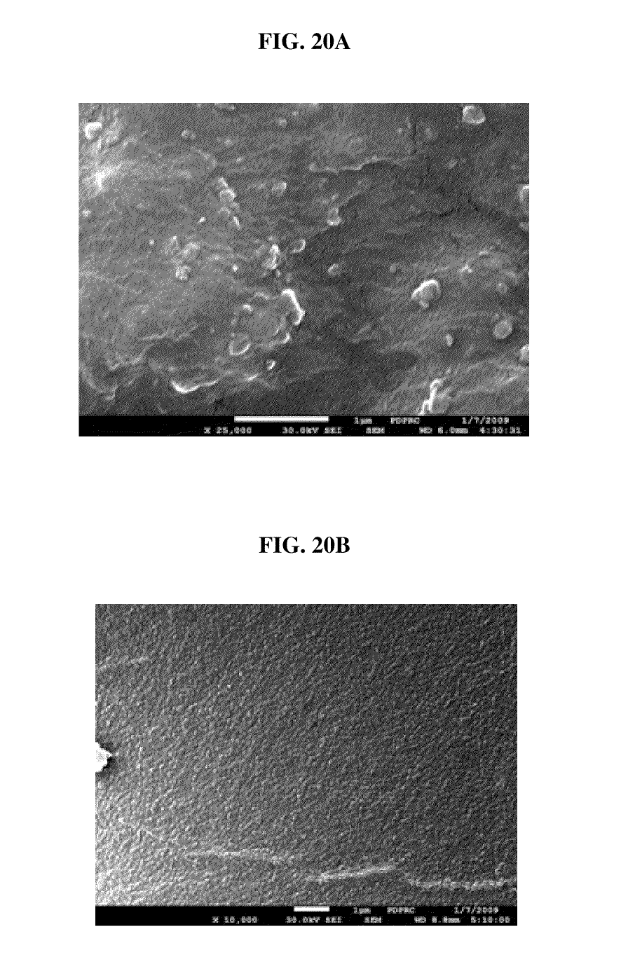

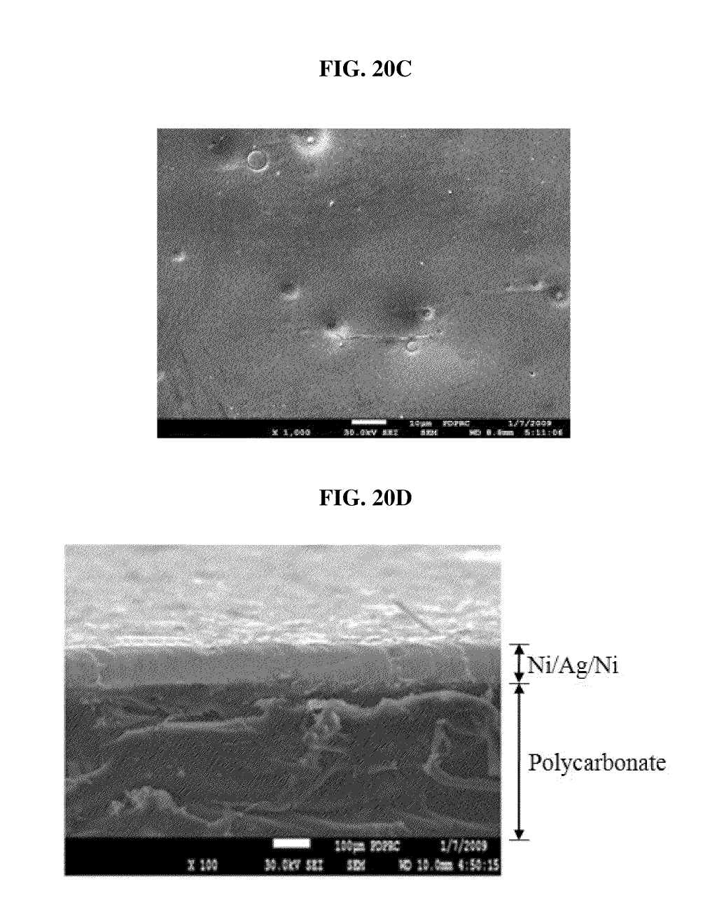

FIG. 20A, FIG. 20B, FIG. 20C, and FIG. 20D are SEM images of the tri-structure internal antenna 110 for each operation. Specifically, FIG. 20A shows a surface of the deposition layer 120 sputter deposited on the substrate 3. FIG. 20B shows a surface of the conductive layer 130 sputter deposited on the deposition layer. And FIG. 20C shows a surface of the protecting layer 140 sputter deposited on the conductive layer 130. A total thickness of the tri-structure internal antenna 110 manufactured as described above may be about 1.5 μm. FIG. 20D shows a measured thickness from an interfacial tension image of the tri-structure internal antenna 110.

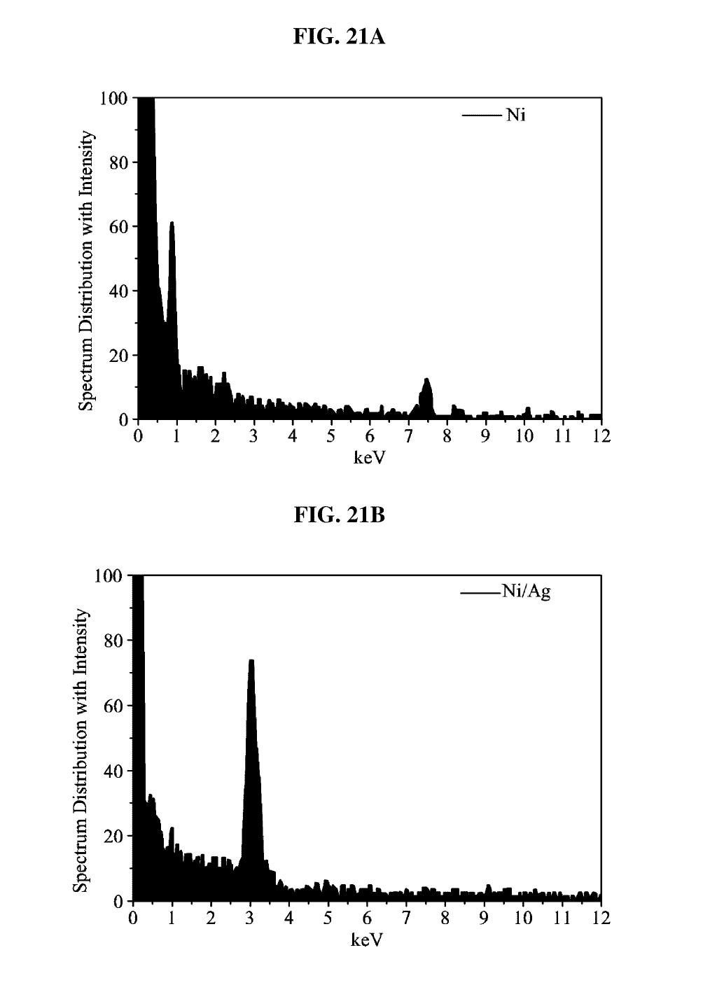

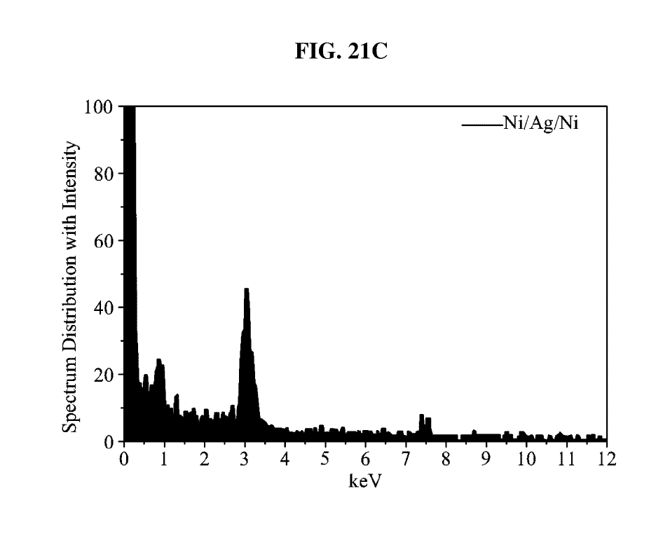

FIG. 21A, FIG. 21B, and FIG. 21C are analysis diagrams illustrating X-ray diffraction pattern images obtained by using an XRD capable of representing a material component composition ratio of the deposition layer 120, the conductive layer 130, and the protecting layer 140 of the tri-structure internal antenna 110. FIG. 21A illustrates a spectra image of the deposition layer 120, FIG. 21B illustrates a spectra image of the conductive layer 130 deposited on the deposition layer 120, and FIG. 21C illustrates a spectra image of the protecting layer 140 deposited on the deposition layer 120 and the conductive layer 130. A voltage applied to measure the material component composition ratio was 0 keV to 12 keV.

Referring to FIG. 21A, the deposition layer 120 shows the material component composition ratio at 0.743 keV, 0.762 keV, 0.851 keV, and 7.478 keV, and shows a peak-to-peak characteristic distribution composition ratio at 8.265 keV, which is similar to FIG. 16A. Also, referring to FIG. 21B, the conductive layer 130 shows the material component composition ratio at 2.643 keV, 2.806 keV, and 2.984 keV, and shows the peak-to-peak characteristic distribution composition ratio at 3.151 keV, which is similar to FIG. 16B. Referring to FIG. 21C, the zo protecting layer 140 shows both the material component composition ratio at 0.743 keV, 0.762 keV, 0.851 keV, and 7.478 keV that is the material component composition ratio of nickel, and the material component composition ratio at 3 keV, 2.806 keV, and 2.984 keV that is the material component composition ratio of silver.

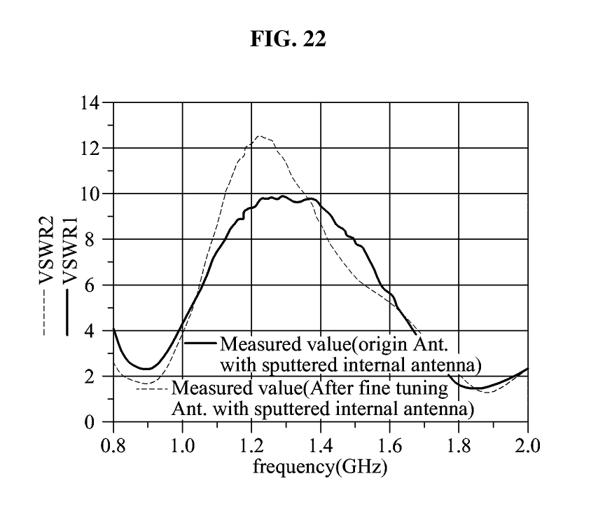

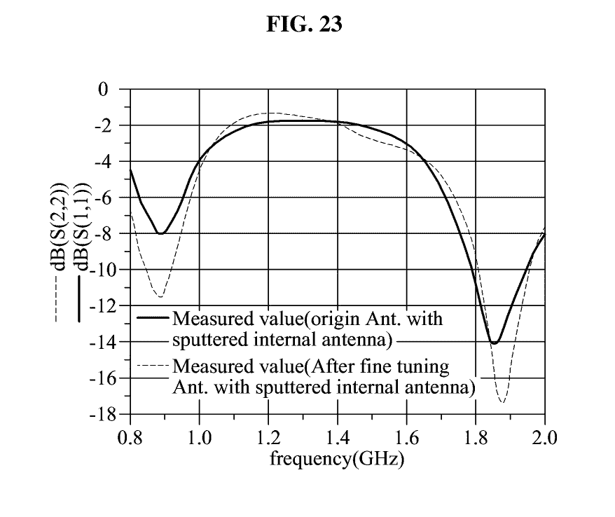

FIG. 22 and FIG. 23 are graphs illustrating results of measuring an SWR and S₁₁, respectively, of the tri-structure internal antenna 110. The graphs of FIG. 22 and FIG. 23 each show initial measurement values and optimized values. Here, a translation of the SWR of the tri-structure internal antenna 110 was performed by evaluating an SWR characteristic using a network analyzer. An operation of optimizing an s-parameter extracted from each antenna component using a matching network was performed. It can be seen from the graphs of FIG. 22 and FIG. 23 that the measured SWR and S₁₁ of the tri-structure internal antenna 110 show stable characteristics.

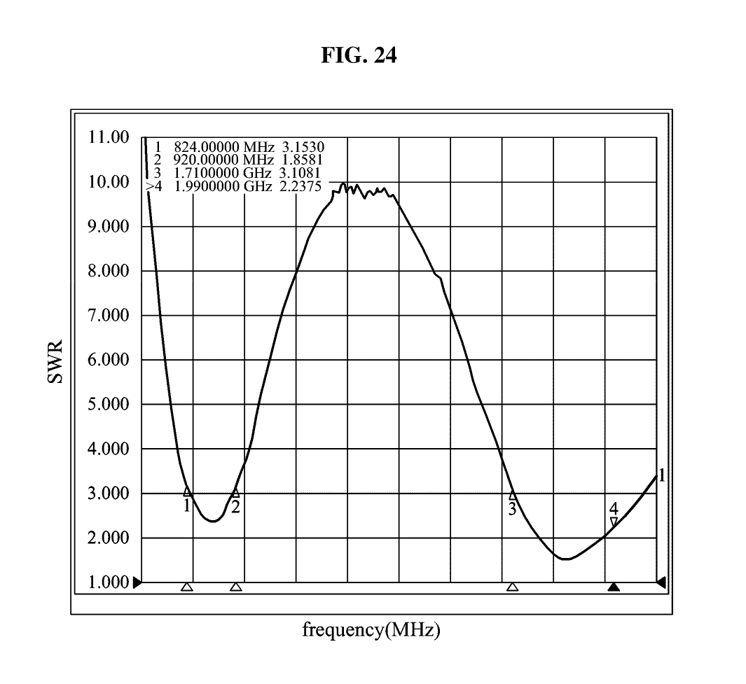

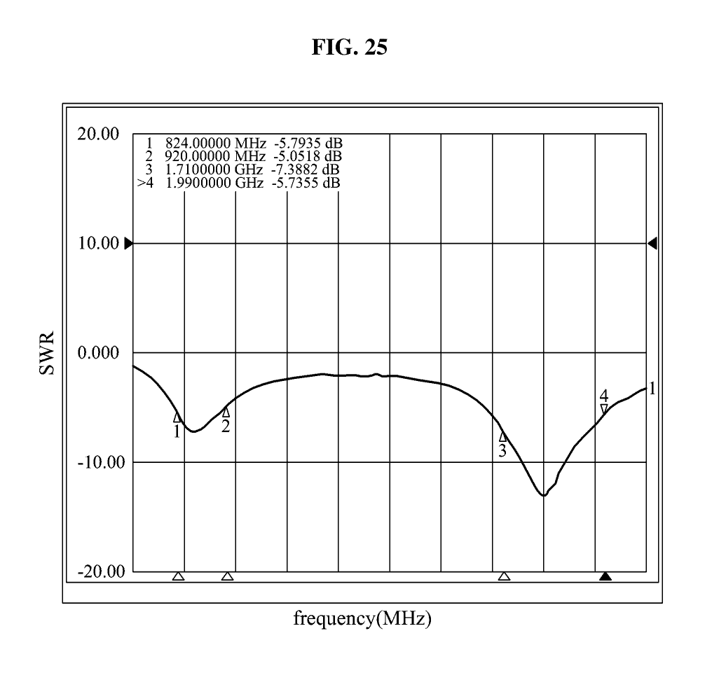

FIG. 24 and FIG. 25 are graphs illustrating results of measuring an actual SWR of the tri-structure internal antenna 110 using a network analyzer. FIG. 24 shows that the measured SWR characteristic of the tri-structure internal antenna 110 formed a double resonance term of 3.15 and 1.86 at 824 MHz and 920 MHz, respectively, and of 3.11 and 2.24 at 1710 MHz and 1990 MHz, respectively, and had a quad-band coverage. Similarly, FIG. 25 shows that the measured S₁₁ of the tri-structure internal antenna 110 formed the double resonance term of −5.79 dB and −5.05 dB at 824 MHz and 920 MHz, respectively, and of −7.39 dB and −5.74 dB at 1710 MHz and 1990 MHz, respectively, and had the quad-band coverage.

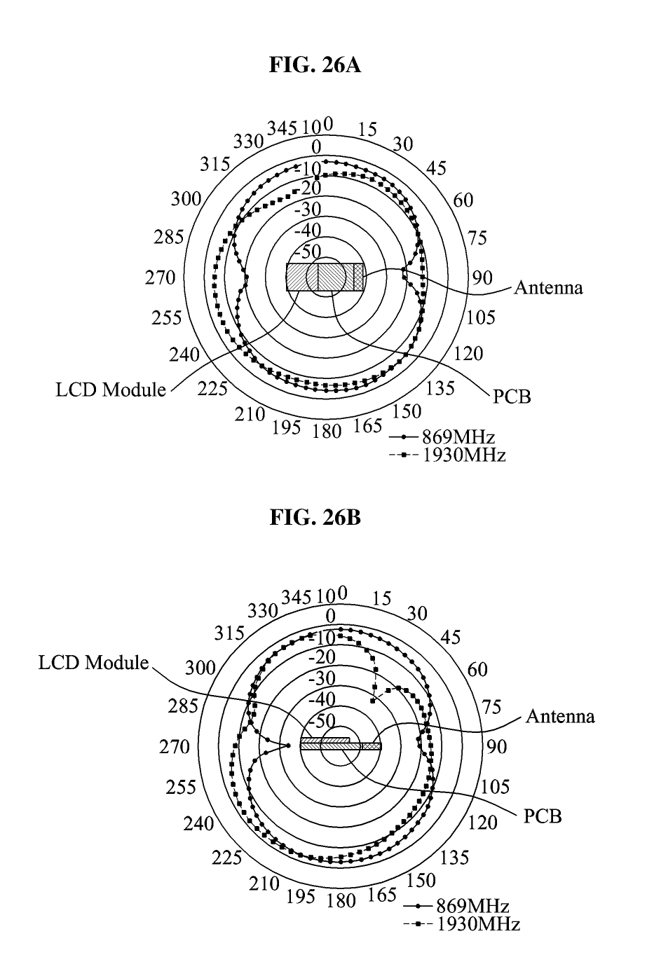

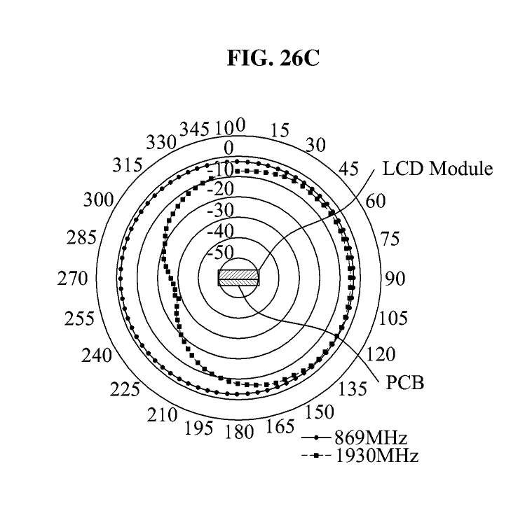

FIG. 26A, FIG. 26B, and FIG. 26C are radiation patterns with respect to an E-plane and an H-plane that are two-dimensional (2D) antenna gain measurement results of the tri-structure internal antenna 110. Here, f=869 MHz and 1930 MHz. FIG. 26A corresponds to an E1-plane, FIG. 26B corresponds to an E2-plane, and FIG. 26C corresponds to the H-plane.

Referring to the radiation patterns of FIG. 26A, FIG. 26B, and FIG. 26C, the measurements of a peak gain and an average gain of the E1-plane, the E2-plane, and the H-plane were measured in a Cellular Telecommunication Industry Association (CTIA) chamber. The E-1 plane (y-z plane) exhibited a peak gain of −2.50 dBi and an average gain of −5.97 dBi at 869 MHz, and the E-1 plane (y-z plane) exhibited a peak gain of −4.47 dBi and an average gain of −7.34 dBi at 1930 MHz. Also, the E2-plane (x-z plane) exhibited a peak gain of −2.28 dBi and an average gain of −5.69 dBi at 869 MHz, and the E2-plane (x-z plane) exhibited a peak gain of −1.95 dBi and an average gain of −5.69 dBi at 1930 MHz. Also, the H-plane (x-y plane) exhibited a peak gain of −2.53 dBi and an average gain of −2.93 dBi at 869 MHz, and the H-plane (x-y plane) exhibited a peak gain of −3.72 dBi and an average gain of −7.23 dBi at 1930 MHz.

The radiation patterns of FIG. 26A, FIG. 26B, and FIG. 26C illustrate that the tri-structure internal antenna 110 may operate as an antenna of a mobile terminal. Table 3 below relates to the gain measurement graphs with respect to the E1-plane (y-z plane), the E2-plane (x-z plane), and the H-plane (x-y plane) of the tri-structure internal antenna 110. Here, f=869 MHz and 1930 MHz. Gain measurement values of the radiation patterns of FIG. 26A, FIG. 26B, and FIG. 26C are shown in the following Table 3:

TABLE 3

| | | | |
|---|---|---|---|
| Frequency [symbol] | E1-plane (y-z plane) [symbol] | E2-plane (x-z plane) [symbol] | H-plane (x-y plane) [symbol] |

Gain Average

[symbol]

| | | | |
|---|---|---|---|
| 869 MHz [symbol] | −5.97 dBi [symbol] | −5.69 dBi [symbol] | −2.93 dBi [symbol] |
| 1930 MHz [symbol] | −7.34 dBi [symbol] | −6.67 dBi [symbol] | −7.23 dBi [symbol] |

Gain Peak

[symbol]

| | | | |
|---|---|---|---|
| 869 MHz [symbol] | −2.50 dBi, 0 deg [symbol] | −2.28 dBi, 355 deg [symbol] | −2.53 dBi, 315 deg [symbol] |
| 1930 MHz [symbol] | −4.47 dBi, 150 deg [symbol] | −1.95 dBi, 225 deg [symbol] | −3.72 dBi, 125 deg [symbol] |

Gain min

[symbol]

| | | | |
|---|---|---|---|
| 869 MHz [symbol] | −22.03 dBi, 90 deg [symbol] | −33.65 dBi, 270 deg [symbol] | −3.49 dBi, 75 deg [symbol] |
| 1930 MHz [symbol] | −16.03 dBi, 335 deg [symbol] | −32.30 dBi, 35 deg [symbol] | −29.09 dBi, 250 deg [symbol] |

Gain Deviation (Gain Peak − Gain min)

[symbol]

| | | | |
|---|---|---|---|
| 869 MHz [symbol] | 19.53 dB [symbol] | 31.37 dB [symbol] | 0.96 dB [symbol] |
| 1930 MHz [symbol] | 11.56 dB [symbol] | 30.35 dB [symbol] | 25.37 dB [symbol] |

As described above, in the case of a multi-layer thin film internal antenna, for example, the heterostructure internal antenna 10 and the tri-structure internal antenna 110, electrons may flow within a conductor at a low frequency, and the electrons may flow along the surface of the conductor while the frequency changes from the low frequency to a high frequency. Accordingly, it is possible to provide an antenna having enhanced characteristics, using the deposition layer 20 or 120 and the conductive layer 30 or 130 that are formed using a conductive material.

Also, the multi-layer thin film internal antenna may be applicable to a portable terminal and to other devices that may use an antenna with a transceiver. For example, the multi-layer thin film internal antenna may be applicable to a frequency modulation (FM) band, a portable terminal band, and a frequency band of a few of GHz, and may also be applicable to a transmission and reception (Tx/Rx) diversity antenna of a 4^{th} Generation (4G) system, and an antenna provided in a chipset.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A multi-layer thin film internal antenna, comprising:
a sputter deposited deposition layer disposed on a substrate and comprising a first conductive material; and
a sputter deposited conductive layer disposed on the deposition layer and comprising a second conductive material.

2. The antenna of claim 1, further comprising:
a planarization layer disposed between the substrate and the deposition layer.

3. The antenna of claim 2, wherein the planarization layer has a thickness of 75 μm to 85 μm by spraying a hardener towards the substrate at a temperature of 75° C. to 85° C. for 85 minutes to 95 minutes.

4. The antenna of claim 1, wherein the first conductive metal comprises nickel (Ni) and the second conductive material comprises silver (Ag).

5. The antenna of claim 4, wherein:
the deposition layer has a thickness of 2500 Å to 3500 Å by sputter depositing the nickel at a power of 6.5 kW to 7.5 kW in a plasma atmosphere for 175 to 185 seconds, and the conductive layer has a thickness of 7500 Å to 8500 Å by sputter depositing the silver at a power of 6.5 kW to 7.5 kW in the plasma atmosphere for 1450 to 1550 seconds.

6. The antenna of claim 1, further comprising:
a protecting layer disposed on the conductive layer and formed by using the sputtering deposition method.

7. The antenna of claim 6, wherein nickel is used as a sputtering target material, and the protecting layer has a thickness of 3500 Å to 4500 Å by sputter depositing the nickel at a power of 6.5 kW to 7.5 kW in a plasma atmosphere for 200 seconds to 300 seconds.

8. A multi-layer thin film internal antenna, comprising:
a plurality of sputter deposited layers each comprising conductive materials, the layers being disposed in a multi-layer structure on a substrate,
wherein a total thickness of the layers is 1.0 μm to 1.6 μm.

9. The antenna of claim 8, wherein the plurality of layers is disposed on a planarization layer comprising a hardener sprayed toward the substrate at a temperature of 75° C. to 85° C. for 85 minutes to 95 minutes.

10. The antenna of claim 8, wherein:
the plurality of layers comprises a deposition layer and a conductive layer that are sequentially sputter deposited on the substrate by using nickel and silver, respectively, as sputtering target materials, and
the deposition layer has a thickness of 2500 Å to 3500 Å by sputter depositing the nickel at a power of 6.5 kW to 7.5 kW in a plasma atmosphere for 175 seconds to 185 seconds, and the conductive layer has a thickness of 7500 Å to 8500 Å by sputter depositing the silver at a power of 6.5 kW to 7.5 kW in the plasma atmosphere for 1450 seconds to 1550 seconds.

11. The antenna of claim 10, wherein the plurality of layers further comprises:
a protecting layer formed on the conductive layer using nickel as a sputtering target material and having a thickness of 3500 Å to 4500 Å by sputter depositing the nickel at a power of 6.5 kW to 7.5 kW in the plasma atmosphere for 200 seconds to 300 seconds.

12. A method for manufacturing a multi-layer thin film internal antenna, the method comprising:
sputter depositing, in a pattern, a deposition layer on a substrate of a terminal body using a first conductive material; and
sputter depositing, in the pattern, a conductive layer on the substrate using a second conductive material.

13. The method of claim 12, further comprising:
forming a planarization layer on the substrate to a thickness of 75 μm to 85 μm by spraying a hardener towards the substrate at a temperature of 75° C. to 85° C. for 85 minutes to 95 minutes.

14. The method of claim 12, further comprising:
disposing a mask on the substrate, the mask having a pattern corresponding to a pattern of the antenna.

15. The method of claim 14, wherein:
forming the deposition layer comprises forming the deposition layer to a thickness of 2500 Å to 3500 Å by sputter depositing nickel at a power of 6.5 kW to 7.5 kW in a plasma atmosphere for 175 seconds to 185 seconds, and
forming the conductive layer comprises forming the conductive layer to a thickness of 7500 Å to 8500 Å by sputter depositing the silver at a power of 6.5 kW to 7.5 kW in a plasma atmosphere for 1450 seconds to 1550 seconds.

16. The method of claim 12, further comprising:
sputter depositing a protecting layer on the conductive layer,
wherein the protecting layer uses nickel as a sputtering target material, and the protecting layer is formed to a thickness of 3500 Å to 4500 Å by sputter depositing the nickel at a power of 6.5 kW to 7.5 kW in a plasma atmosphere for 200 seconds to 300 seconds.

17. The method of claim 12, wherein the conductive layer is formed on the deposition layer.

18. The method of claim 13, wherein the deposition layer is formed on the planarization layer, and the conductive layer is formed on the deposition layer.

19. A terminal comprising:
a terminal body comprising a substrate; and
a multi-layer thin film internal antenna disposed in a multi-layer structure on the substrate,
wherein the antenna comprises:
a sputter deposited deposition layer comprising a first conductive material on the substrate; and
a sputter deposited conductive layer comprising a second conductive material on the deposition layer.

20. The terminal of claim 19, further comprising a planarization layer is disposed between the substrate and the deposition layer.

21. The terminal of claim 20, wherein the planarization layer has a thickness of 75 μm to 85 μm by spraying a hardener towards the substrate at a temperature of 75° C. to 85° C. for 85 minutes to 95 minutes.

22. The terminal of claim 19, wherein the first conductive material comprises nickel and the second conductive material comprises silver.

23. The terminal of claim 22, wherein:
the deposition layer has a thickness of 2500 Å to 3500 Å by sputter depositing the nickel at a power of 6.5 kW to 7.5 kW in a plasma atmosphere for 175 seconds to 185 seconds, and
the conductive layer has a thickness of 7500 Å to 8500 Å by sputter depositing the silver at a power of 6.5 kW to 7.5 kW in the plasma atmosphere for 1450 seconds to 1550 seconds.

24. The terminal of claim 19, further comprising:
a sputter deposited protecting layer disposed on the conductive layer.

25. The terminal of claim 24, wherein the protecting layer uses the nickel as a sputtering target material, and the protecting layer has a thickness of 3500 Å to 4500 Å by sputter depositing the nickel at a power of 6.5 kW to 7.5 kW in a plasma atmosphere for 200 seconds to 300 seconds.
